(19) United States
(12) Patent Application Publication
(10) Pub. No.: US 2014/0090706 A1
(43) Pub. Date: Apr. 3, 2014

(54) SOLAR CELL APPARATUS AND METHOD OF FABRICATING THE SAME

(71) Applicants: CHUNG-ANG UNIVERSITY INDUSTRY-ACADEMY CORPORATION FOUNDATION, Seoul (KR); LG INNOTECK CO., LTD., Seoul (KR)

(72) Inventors: Chul Hwan CHOI, Seoul (KR); In Hwan CHOI, Seoul (KR)

(73) Assignees: CHUNG-ANG UNIVERSITY INDUSTRY-ACADEMY COOPERATION FOUNDATION, Seoul (KR); LG INNOTEK CO., LTD., Seoul (KR)

(21) Appl. No.: 14/123,130

(22) PCT Filed: May 31, 2012
(86) PCT No.: PCT/KR2012/004294

§ 371 Date: Nov. 29, 2013

(30) Foreign Application Priority Data
May 31, 2011 (KR) 10-2011-0052488

(51) Int. Cl. H01L 31/0216; H01L 31/18

(52) U.S. Cl. CPC H01L 31/02167; H01L 31/18
USPC 136/256; 438/98; 136/252

(57) ABSTRACT

A solar cell apparatus according to the embodiment includes a substrate; a back electrode layer on the substrate; a light absorbing layer on the back electrode layer; a first buffer layer including CdS on the light absorbing layer; a second buffer layer including Zn on the first buffer layer; and a window layer on the second buffer layer.

### TECHNICAL FIELD

The embodiment relates to a solar cell apparatus and a method of fabricating the same.

### BACKGROUND ART

Recently, as energy consumption is increased, a solar cell apparatus has been developed to convert solar energy into electric energy.

In particular, a CIGS-based solar cell apparatus, which is a PN hetero junction apparatus having a substrate structure including a glass substrate, a metallic back electrode layer, a P type CIGS-based light absorbing layer, a buffer layer, and an N type window layer, has been extensively used.

In such a solar cell apparatus, studies and research have been performed to improve electric characteristics of the solar cell apparatus, such as the low resistance and high transmittance rate.

### DISCLOSURE OF INVENTION

### Technical Problem

The embodiment provides a solar cell apparatus, which can be fabricated through an environmental-friendly scheme by forming a buffer layer including Cd having a thin thickness and can improve the photoelectric conversion efficiency, and a method of fabricating the same.

### Solution to Problem

A solar cell apparatus according to the embodiment includes a substrate; a back electrode layer on the substrate; a light absorbing layer on the back electrode layer; a first buffer layer including CdS on the light absorbing layer; a second buffer layer including Zn on the first buffer layer; and a window layer on the second buffer layer.

A method of fabricating a solar cell apparatus according to the embodiment includes the steps of forming a back electrode layer on a substrate; forming a light absorbing layer on the back electrode layer; forming a first buffer layer including CdS on the light absorbing layer; forming a second buffer layer including Zn on the first buffer layer; and forming a window layer on the second buffer layer.

### Advantageous Effects of Invention

According to the solar cell apparatus of the embodiment, CdS included in the buffer layer has a thin thickness, so the environmental pollution caused by the CdS, which is a toxic heavy metal, can be prevented and the solar cell apparatus may have thermal stability and superior electric characteristics.

### BRIEF DESCRIPTION OF DRAWINGS

FIG. 1 is a sectional view showing a solar cell apparatus according to the embodiment;

FIG. 2 is a graph showing materials injected to form a second buffer layer according to the embodiment;

FIG. 3 is a view showing the structure of a second buffer layer according to the embodiment;

FIG. 4 is a view showing the quantum efficiency as a function of the wavelength of a solar cell apparatus according to the embodiment; and

FIGS. 5 to 8 are sectional views showing a method for fabricating a solar cell apparatus according to the embodiment.

### MODE FOR THE INVENTION

In the description of the embodiments, it will be understood that when a substrate, a layer, a film or an electrode is referred to as being on or under another substrate, another layer, another film or another electrode, it can be directly or undirectly on the other substrate, the other layer, the other film, or the other electrode, or one or more intervening layers may also be present. Such a position of the layer has been described with reference to the drawings. The size of the elements shown in the drawings may be exaggerated for the purpose of explanation and may not utterly reflect the actual size.

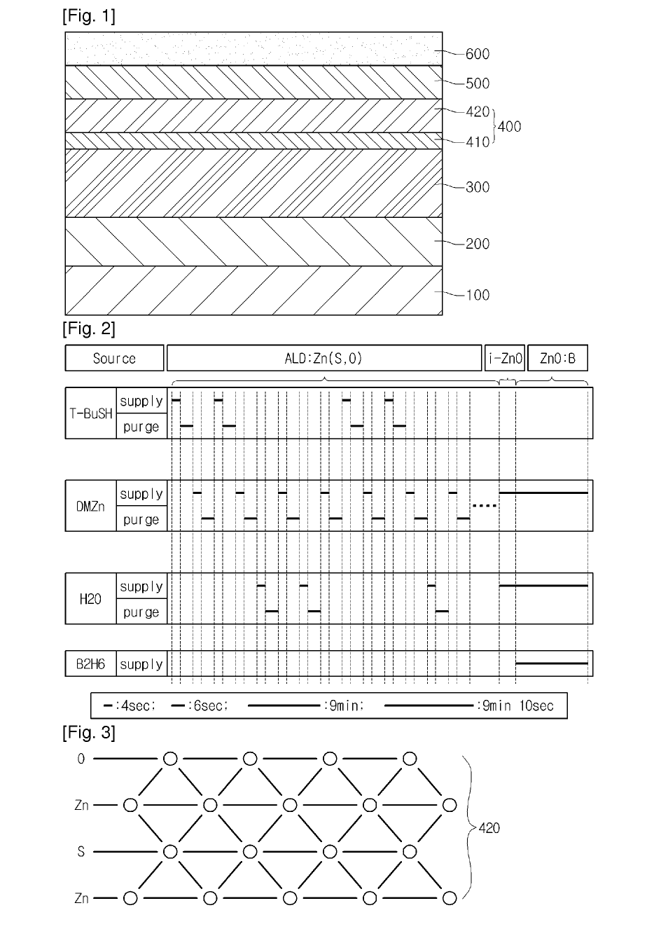

FIG. 1 is a sectional view showing a solar cell apparatus according to the embodiment. Referring to FIG. 1, a solar cell panel includes a support substrate 100, a back electrode layer 200, a light absorbing layer 300, a buffer layer 400 including first and second buffer layers 410 and 420, and a window layer 500.

The support substrate 100 may include an insulator. The support substrate 100 may be a glass substrate, a plastic substrate such as polymer or a metal substrate. Meanwhile, the support substrate 100 may include a ceramic substrate including alumina, a stainless steel (SUS) substrate, or a polymer substrate having flexibility. The support substrate 100 may be transparent, flexible or rigid.

The back electrode layer 200 is disposed on the support substrate 100. The back electrode layer 200 is a conductive layer. The back electrode layer 200 allows migration of charges generated from the light absorbing layer 300 of the solar cell apparatus such that current can flow out of the solar cell apparatus. To this end, the back electrode layer 200 may have high electric conductivity and low specific resistance.

In addition, the back electrode layer 200 must have the high-temperature stability when the heat treatment process is performed under the sulfide (S) or selenium (Se) atmosphere to form the CIGS compound. In addition, the back electrode layer 200 may have superior adhesive property with respect to the support substrate 100 in such a manner that the back electrode layer 200 may not be delaminated from the support substrate 100 due to difference of the thermal expansion coefficient.

The back electrode layer 200 may include one of Mo, Au, Al, Cr, W and Cu. Among the above elements, the Mo may represent the thermal expansion coefficient similar to that of the support substrate 100, so the Mo has superior adhesive property with respect to the support substrate 100, thereby preventing the back electrode layer 200 from being delaminated from the support substrate 100. In detail, the Mo may satisfy the above properties required for the back electrode layer 200.

The back electrode layer 200 may include at least two layers. In this case, at least two layers may be formed by using the same metal or different metals.

The light absorbing layer 300 is formed on the back electrode layer 200. The light absorbing layer 300 may include P type semiconductor compounds. In detail, the light absorbing layer 300 may include group I-III-VI compounds. For instance, the light absorbing layer 300 may include the Cu(In,Ga)Se₂ (CIGS) crystal structure, the Cu(In)Se₂ crystal structure, or the Cu(Ga)Se₂ crystal structure. The light absorbing layer 300 has an energy bandgap in the range of about 1.1 eV to about 1.8 eV.

The buffer layer 400 is disposed on the light absorbing layer 300. The solar cell apparatus having the light absorbing layer 300 including the CIGS compound may form the PN junction between the CIGS compound layer, which is a P type semi-conductor, and the window layer 500, which is the N type semiconductor. However, since there is great difference in lattice constant and bandgap energy between the CIGS compound layer and the window layer 500, the buffer layer 400 having the intermediate bandgap is required to form the desired junction.

The buffer layer 400 includes the first and second buffer layers 410 and 420. In general, the buffer layer includes CdS or ZnS. It is advantageous in terms of the energy conversion efficiency if the buffer layer is formed by depositing the CdS through the CBD scheme. However, since the CdS absorbs light having the wavelength of 500 nm or less, which is shorter than the energy bandgap, the energy conversion efficiency may not be maximized. In addition, the CdS includes Cd, which is a heavy metal, so studies and research have been actively performed to substitute for the CdS.

The ZnS has been used as a substitute for the CdS. However, the ZnS is not stable and the energy conversion efficiency is lower than that of the CdS. The ZnS has the energy bandgap greater than that of ZnO, which is generally used for the window layer, so the light loss can be reduced. However, the diffusion degree of Zn atoms in the light absorbing layer is significantly greater than that of Cd, so the thermal stability may be degraded. In addition, the desired diode characteristic may not be obtained due to the band offset of the conduction band. The embodiment provides the buffer layer, which can maintain advantages of the CdS buffer layer while minimizing disadvantages and maximizing the energy conversion efficiency of the solar cell apparatus.

According to the embodiment, the first buffer layer 410 is formed on the light absorbing layer 300. The first buffer layer 410 may include CdS. The first buffer layer 410 may have a thickness of 20 nm or less, preferably, 10 nm or less. Since the first buffer layer 410 including the CdS has the thin thickness, the amount of light having the wavelength of 500 nm or less absorbed in the buffer layer can be minimized.

The second buffer layer 420 is formed on the first buffer layer 410. The second buffer layer 420 can be formed by depositing Zn, S or oxygen ions through the MOCVD scheme or the ALD (atomic layer deposition) scheme.

When the second buffer layer 420 is formed through the MOCVD scheme, ZnS and ZnO are sequentially and alternately formed. For instance, the ZnS is laminated with the thickness in the range of 0.3 nm to 0.7 nm and the ZnO is laminated with the thickness in the range of 3 nm to 7 nm, in which each layer can be laminated several times. The second buffer layer 420 may have a thickness in the range of 60 nm to 70 nm. In addition, In₂Se₃ can be formed instead of ZnS.

When the second buffer layer 420 is formed through the ALD scheme, atomic layers including Zn, S, Zn and O are alternately laminated. The ALD scheme to form the second buffer layer 420 will be described later in detail with reference to FIGS. 2 and 3.

The window layer 500 is disposed on the buffer layer 400. The window layer 500 is a transparent conductive layer. In addition, the window layer 500 has resistance higher than that of the back electrode layer 200.

The window layer 500 includes oxide. For instance, the window layer 500 may include zinc oxide, indium tin oxide (ITO) or indium zinc oxide (IZO).

In addition, the window layer 500 may include Al doped zinc oxide (AZO) or Ga doped zinc oxide (GZO).

According to the solar cell apparatus of the embodiment, CdS included in the buffer layer 400 has a thin thickness, so the environmental pollution caused by the CdS, which is a toxic heavy metal, can be prevented and the solar cell apparatus may have thermal stability and superior electric characteristics.

FIG. 2 is a graph showing materials injected to form the second buffer layer 420 according to the embodiment, and FIG. 3 is a view showing the structure of the second buffer layer 420 according to the embodiment.

According to the embodiment, the second buffer layer 420 is formed through the ALD scheme, but the embodiment is not limited thereto. If the second buffer layer 420 is formed through the ALD scheme, T-BuSH is injected for four seconds as a source of S and then purged for six seconds. After that, DMZn is injected for four seconds as a source of Zn and then purged for six seconds. Thereafter, T-BuSH is injected again for four seconds as a source of S and then purged for six seconds. After that, DMZn is injected again for four seconds as a source of Zn and then purged for six seconds. Thus, as shown in FIG. 3, Zn and S atomic layers are deposited through the above process.

After that, DMZn is injected for four seconds as a source of Zn and then purged for six seconds and H₂O is injected for four seconds as a source of O and the purged for six seconds. The Zn and S atomic layers are deposited by repeating the above process.

Thus, Zn, S, Zn and O elements are sequentially laminated so that the second buffer layer 420 is formed. At this time, the second buffer layer 420 may have the thickness in the range of 60 nm to 70 nm.

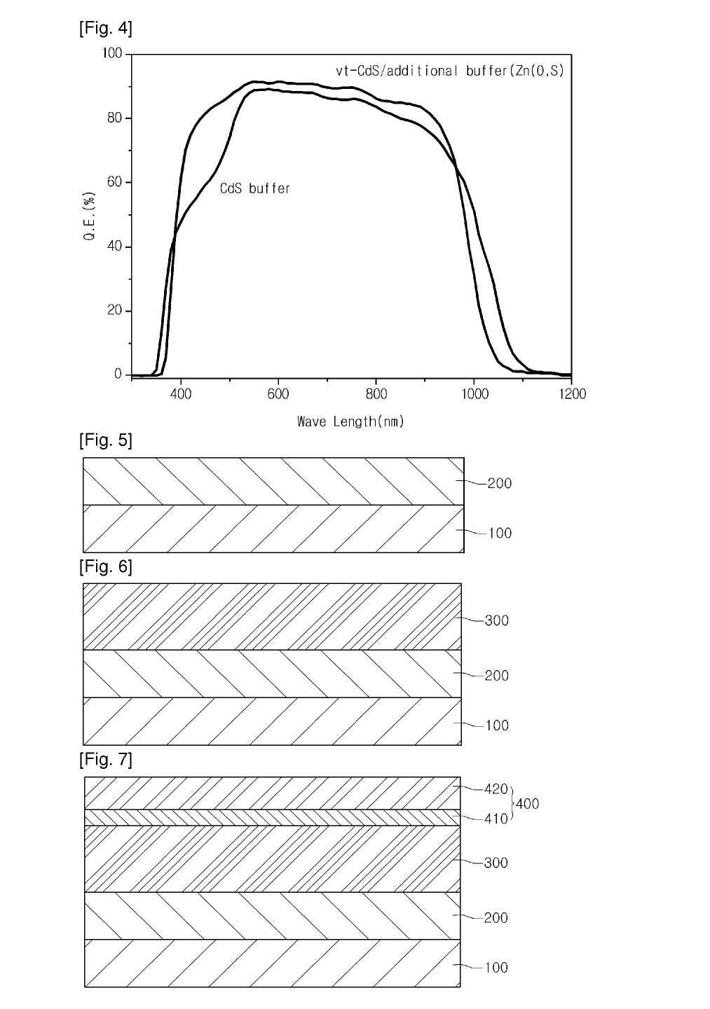

FIG. 4 is a view showing the quantum efficiency as a function of the wavelength of the solar cell apparatus according to the embodiment. As shown in FIG. 4, when comparing with the case in which the buffer layer is formed on the light absorbing layer 300 by using CdS only, the quantum conversion efficiency is increased if the first buffer layer 410 including the CdS is formed with the thickness of 20 nm or less and the second buffer layer 420 having ZnS and ZnO, which are sequentially formed, is formed on the first buffer layer 410.

FIGS. 5 to 8 are sectional views showing the method of fabricating the solar cell apparatus according to the embodiment. The above description about the solar cell apparatus will be basically incorporated in the description about the method of fabricating the solar cell by reference.

Referring to FIGS. 5 and 6, the back electrode layer 200 is formed on the support substrate 100. The back electrode layer 200 may be deposited by using Mo. The first electrode layer 210 can be formed through a PVD (physical vapor deposition) process or a plating process.

In addition, an additional layer, such as a diffusion barrier layer, can be formed between the support substrate 100 and the back electrode layer 200.

Then, the light absorbing layer 300 is formed on the back electrode layer 200. For instance, Cu, In, Ga and Se are simultaneously or independently evaporated to form the CIGS-based light absorbing layer 300, or the light absorbing layer 300 can be formed through the selenization process after forming a metal precursor layer.

In detail, the metal precursor layer is formed on the back electrode layer 200 by performing the sputtering process using a Cu target, an In target, and a Ga target.

Then, the selenization process is performed to form the CIGS-based light absorbing layer 300.

In addition, the sputtering process using the Cu target, the In target, and the Ga target and the selenization process can be simultaneously performed.

Further, the CIS-based or CIG-based light absorbing layer 300 can be formed through the selenization process and the sputtering process using only the Cu and In targets or the Cu and Ga targets.

During the process for forming the light absorbing layer 300, sodium included in the barrier layer may be separated from the barrier layer and may diffuse into the light absorbing layer 300. Thus, the charge concentration of the light absorbing layer 300 may be increased, so that the photoelectric conversion efficiency of the solar cell apparatus can be improved.

Referring to FIG. 7, the CdS is deposited on the light absorbing layer through the sputtering process or the CBD process to form the first buffer layer 410. At this time, the first buffer layer 410 has the thickness of 20 nm or less, preferably, 10 nm or less.

Then, the second buffer layer 420 is formed on the first buffer layer 410. The second buffer layer 420 can be formed by sequentially and repeatedly laminating Zn (S and O) layers through the MOCVD scheme or by alternately laminating Zn, S, Zn and O atomic layers through the ALD scheme.

In addition, indium zinc oxide (IZO) can be formed on the second buffer layer 420.

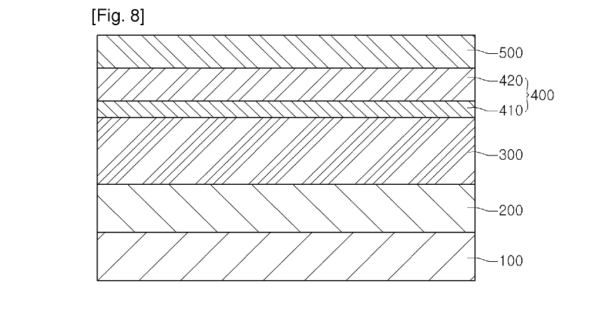

Referring to FIG. 8, the window layer 500 is formed on the buffer layer 400. The window layer 500 can be formed by depositing transparent material on the buffer layer 400. The window layer 500 may include ZnO, but the embodiment is not limited thereto. In addition, the window layer 500 may include boron.

Any reference in this specification to one embodiment, an embodiment, example embodiment, etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell apparatus comprising:
a substrate;
a back electrode layer on the substrate;
a light absorbing layer on the back electrode layer;
a first buffer layer including CdS on the light absorbing layer;
a second buffer layer including Zn on the first buffer layer; and
a window layer on the second buffer layer.

2. The solar cell apparatus of claim 1, wherein the first buffer layer has a thickness of 20 nm or less.

3. The solar cell apparatus of claim 1, wherein the second buffer layer includes sulfide (S) and oxygen (O).

4. The solar cell apparatus of claim 3, wherein the second buffer layer is formed by repeatedly laminating ZnS and ZnO.

5. The solar cell apparatus of claim 4, wherein the ZnS has a thickness in a range of 0.3 nm to 0.7 nm, and the ZnO has a thickness in a range of 3 nm to 7 nm.

6. The solar cell apparatus of claim 3, wherein the second buffer layer is formed by repeatedly laminating Zn, S and O atomic layers.

7. The solar cell apparatus of claim 1, wherein the second buffer layer has a thickness in a range of 60 nm to 70 nm.

8. The solar cell apparatus of claim 1, wherein the second buffer layer includes In₂Se₃.

9. The solar cell apparatus of claim 1, wherein indium zinc oxide is formed between the second buffer layer and the window layer.

10. The solar cell apparatus of claim 1, wherein the window layer includes ZnO.

11. The solar cell apparatus of claim 10, wherein the window layer includes boron.

12. A method of fabricating a solar cell apparatus, the method comprising:
forming a back electrode layer on a substrate;
forming a light absorbing layer on the back electrode layer;
forming a first buffer layer including CdS on the light absorbing layer;
forming a second buffer layer including Zn on the first buffer layer; and
forming a window layer on the second buffer layer.

13. The method of claim 12, wherein the first buffer layer has a thickness of 10 nm or less.

14. The method of claim 12, wherein the second buffer layer is formed through an ALD (atomic layer deposition) scheme by using Zn, O, and S.
